(19) United States
(12) Patent Application Publication
(10) Pub. No.: US 2004/0131947 A1
(43) Pub. Date: Jul. 8, 2004

(54) Reflective mask structure and method of formation

(75) Inventors: Emily Fisch Gallagher, Burlington, VT (US); Louis M. Kindt, Milton, VT (US); Mark Lawliss, South Burlington, VT (US); Kenneth C. Racette, Fairfax, VT (US); Carey W. Thiel, South Burlington, VT (US)

Correspondence Address: IBM MICROELECTRONICS, INTELLECTUAL PROPERTY LAW, 1000 RIVER STREET, 972 E, ESSEX JUNCTION, VT, 05452, US

(73) Assignee: International Business Machines Corporation, Armonk, NY

(21) Appl. No.: 10/248,300

(22) Filed: Jan. 7, 2003

(51) Int. Cl. G03F 9/00

(52) U.S. Cl. 430/5

(57) ABSTRACT

A reflective mask, useful in extreme ultraviolet lithography (EUVL), and method of formation are disclosed. Instead of patterning an absorbing film stack, as is the case with conventional EUVL masks, the reflective film stack itself is patterned and etched to form a trench in the reflective stack. A hard mask is deposited directly on the reflective substrate. It is patterned and repaired. Then the reflective film is removed in the patterned area to create absorbing trenches. The hard mask may then be stripped or remain in place on the final mask. A liner may be formed on the trench to absorb radiation and protect the sidewalls.

### BACKGROUND OF THE INVENTION

1. Field of the Invention

The invention relates to the mask or template that is used to transform incident radiation into a predetermined pattern. More specifically, the invention relates to the mask used to lithographically pattern photosensitive resist on semiconductor wafers. In particular, the invention relates to the reflective mask required for Extreme Ultraviolet Lithography (EUVL).

2. Background of the Invention

Extreme ultraviolet (EUV) light is absorbed readily by most materials, so masks that transmit a portion of the incident radiation can no longer be used. Instead a reflective mask is employed to either reflect the incident radiation or absorb it. EUVL masks are built on a mask blank formed by depositing a multilayer film onto an ultra low expansion (ULE) substrate. An additional silicon capping layer completes the basic EUVL mask blank, and is the starting point for the mask addressed by this invention. Conventional EUVL masks require a buffer and then an absorber layer to be deposited on the multilayer stack. Additional layers can be deposited anywhere within the film stack for different purposes, such as etch stops or conductive inspection/repair layers. However, these layers do not change the EUVL mask features that are relevant to this invention. The films must be carefully chosen. At a minimum, the films must be compatible with each other, compatible with the EUVL stepper conditions while also demonstrating sufficient etch selectivity, low etch bias, and appropriate EUVL absorbing properties. They must be very thin to minimize the shadowing effect that occurs when the mask is exposed to EUV light at the non-normal incidence angle that is required for reflective exposure of a mask. The mask pattern is formed by coating the absorbing stack with a resist layer and patterning it using standard mask-making processes. A dry etch transfers the pattern through the top absorber layer. Inspection and repair are performed before the final design is transferred through the buffer layer to expose the reflective multilayer surface. The resulting mask is composed of reflective regions where the multilayer surface has been exposed and absorbing regions where the absorbing stack remains.

### BRIEF SUMMARY OF THE INVENTION

### SUMMARY OF THE INVENTION

There is a need for perfectly absorbing regions complemented by perfectly reflecting regions on the EUVL mask. All known film stack combinations have some undesirable attributes. The structure of this invention eliminates the absorber film stack.

There is a need to maintain the quality of the multilayer surface during the manufacturing process used for EUVL masks. Reduced or non-uniform reflectivity compromises the mask quality. Each of the multiple etches, cleans and repair processes deployed to build a conventional EUVL mask has the potential to degrade the reflectivity or reflectivity uniformity. The trench mask of this invention protects the reflective area during all process steps preceding the final mask strip.

A new EUVL mask and method of formation are disclosed. Instead of patterning the absorber and buffer, as in the case with the conventional mask, the multilayer itself is patterned and etched to form a trench in the multilayer. A hard mask is deposited directly on the multilayer substrate. It is patterned, inspected and repaired where defective. Then the multilayer itself is removed through the open areas of the hard mask to create absorbing trenches in the reflective multilayer.

This invention reduces the film demands, since only a sacrificial hard mask is needed on top of the multilayer.

Thus this invention provides for tranformation of incident radiation into a predetermined pattern by a reflective mask which comprise a substrate; and a reflective film, the film having patterned trenches so that the trenches absorb the radiation and the unpatterned areas reflect the radiation. The trenches may also be lined for sidewall protection and to prevent partial reflection at the edges of the multilayers.

This invention also provides a method for forming a reflective mask, comprising the steps of: selecting a mask blank comprised of a substrate and a multilayer film; depositing on the multilayer film a hard mask layer; applying a layer of resist on the hard mask layer; creating an exposure pattern in the resist; developing the exposed resist; forming a pattern in the hard mask layer; and forming a trench in the open areas of the patterned hard mask by etching the exposed multilayer film. The process provides for inspection and repair of the mask.

### BRIEF DESCRIPTION OF THE SEVERAL VIEWS OF THE DRAWINGS

FIG. 1A shows a cross-sectional view of a conventional extreme ultraviolet lithography mask structure comprising a substrate, multilayer stack, a buffer layer and an absorber layer. This mask is defined as the prior art. Prior art may include additional layers such as, but not limited to, etch stops, conductive layers, or backside films which are not included in the figure.

FIG. 2A shows the disclosed EUVL mask structure after transfer of a mask pattern to the multilayer layer, such that the absorber is defined as a trench in the multilayer.

FIG. 2B shows a front cross-sectional view of an extreme ultraviolet lithography (EUVL) mask structure comprising a multilayer stack on a substrate, a hardmask layer and patterned resist.

FIG. 2C shows the EUVL mask structure of FIG. 2A after transfer of a mask pattern to the hardmask layer.

FIG. 2D shows the EUVL mask structure of FIG. 2C after transfer of a mask pattern to the hardmask layer such that defects have been inadvertently created in the absorber layer.

FIG. 2E shows the EUVL mask structure of FIG. 2D with the defects completely repaired.

FIG. 2F shows the EUVL mask structure of FIG. 2A with a sidewall on the trench for improved absorption.

FIG. 2G shows laser reflectance as a function of time during the multilayer etch. This is a laser endpoint trace.

### DETAILED DESCRIPTION OF THE INVENTION

A novel EUVL mask is disclosed. Instead of creating absorbing features on top of the multilayer, as is customary, the absorbing features are etched into the multilayer itself. This can accomplished with a simple process. Some of the process steps are common and known to those in the industry. The new and enabling features will be described herein.

The starting mask blank is not changed from conventional EUVL masks. The EUVL mask blank's essential components are the low thermal expansion substrate and the reflective multilayer stack. The most common reflective coating for EUVL is 40 bilayers of silicon and molybdenum. The thicknesses of the silicon and molybdenum are optimized to produce a peak EUV reflectivity at a wavelength of 13.4-13.6 nm. An additional silicon capping layer is deposited on top to protect the multilayer from processing damage. A hard mask is then deposited directly on the multilayer stack.

The hard mask is the only film required for the trench mask process beyond those required to form the reflective mask blank. The choice of an appropriate film is important. There are two options for the hard mask: it can be a sacrificial layer, which will not be present on the final mask, or it can be a film that is left in place.

If the hard mask is temporary and will be removed, the EUV properties of the material such as absorption and radiation durability no longer matter. Still, there are several factors to be considered. The RIE chemistry used to pattern the hard mask must also have excellent selectivity to the underlying multilayer during the mask open etch so that the capping layer is not damaged should a repair be needed. Since this region of the multilayer will eventually be removed, surface quality is only critical where patterning errors have occurred and additional material is added to repair the defective mask. The hard mask must also have reasonable etch resistance during the transfer of the pattern through the multilayer in the opened areas. Finally, if necessary, there must be a selective process to strip the hard mask while leaving the multilayer unchanged. For this sacrificial hard mask, a thin chromium layer satisfies all of these requirements.

If the hard mask is “permanent”, it remains on the final mask. The permanent hard mask's optical properties and long-term durability are more critical than the temporary hard mask. Generally, films consisting of certain elements and their corresponding nitrides, borides, or carbides, can be used to not only increase the corrosion resistance of the film stack, but also slightly enhance the EUV reflectivity (See U.S. Pat. No. 5,958,605). The permanent hard mask layer could be formed from, for example, Ru or Nb, and would be left on the final mask's reflective regions after the trenches are formed.

An etch is used to transfer the pattern into the multilayer stack. An isotropic, dry etch would work, but a wet etch could be used if the lateral etch rate were suppressed. A fluorine reactive ion etch chemistry is capable of etching both the Mo and the Si layers of the multilayer, along with offering an adequate etch rate and vertical sidewalls. The multilayer etch can be either timed or end-pointed. An adequate over-etching of the multilayer can be allowed. If the hard mask is transparent to EUV light, the trench mask is complete after the final multilayer etch and a subsequent clean. If the hard mask is sacrificial it must be stripped after the multilayer etch, but before the final clean.

Inspection and repair of the hard mask must be done after it is patterned, but before the final multilayer etch. Opaque defects on top of the exposed multilayer must be removed, but damage to the multilayer from staining or localized heating, for example, is permissible since the multilayer will be completely removed in these areas. Clear defects created by the absence of hard mask material in regions must be patched using a process that does not damage the surface of the multilayer such as electron beam assisted deposition. If the hard mask is sacrificial, these repairs must also be completely removed during the hard mask strip.

An enhancement to the mask is a liner layer on the sidewalls of the trench multilayer. The liner can be formed by a variety of methods, which include sputter deposition, electroplating or growth in the presence of a reactive medium such as native oxide growth or chemical vapor deposition. The purpose of the sidewall liner is to increase the printability of the mask by decreasing any blur that would occur by partial reflection at the multilayer edges. This process would be more easily integrated with the sacrificial hard mask because any artifacts of the sidewall process on the top surface would be removed during the hard mask strip. Liner materials that could be deposited include, but are not limited to, TaN, TiN, SiON, and Si₃N₄. Materials that could be electroplated include, but are not limited to, CoNi alloys and Cu. A liner could also be formed by, for example, oxidizing the exposed trench sidewall. All liner materials must be compatible with the mask cleaning strategy. The quality of the coverage is not critical since the liner is an absorptive enhancement, not a critical optical element of the mask. It is the absence of the multilayer in the trench region that is the primary absorbing feature on the mask.

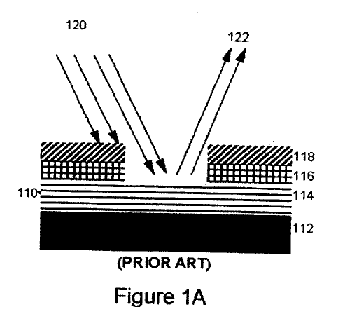

FIG. 1A shows a cross-sectional view of the prior art of an EUVL mask structure 110 which consists of a substrate 112, a multilayer stack 114, a buffer layer 116, and an absorber layer 118. The surface of mask structure 110 is irradiated with EUV light 122 at an incidence angle in the stepper. The incoming EUV light 120 is absorbed by the absorber 118 and reflected by the mulitlayer film stack 114. The reflected EUV light 122 creates the final pattern on the printed wafer.

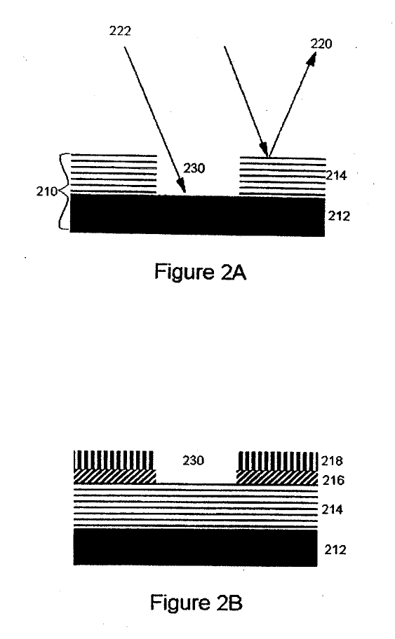

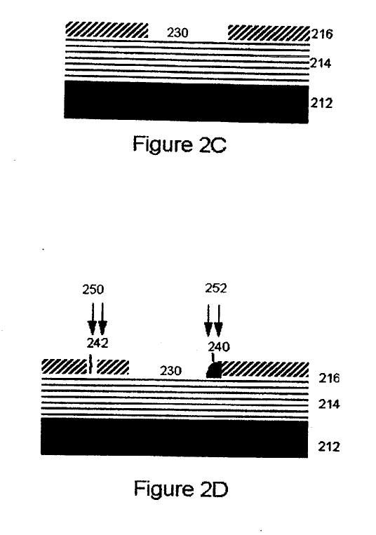

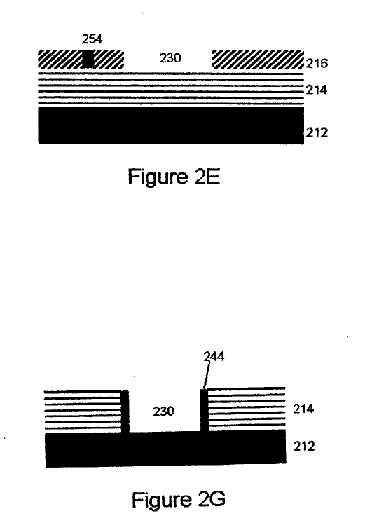

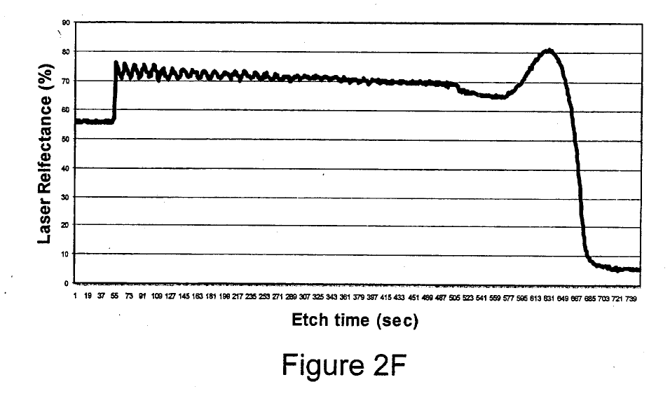

FIG. 2A shows a cross-sectional view of the current invention mask structure 210 which consists of a patterned multilayer stack 214 on a substrate 212. The substrate 212 is typically comprised of a low thermal expansion material. The substrate 212 provides a flat, rigid surface to support the multilayer stack 214 and also to prevent image placement errors due to heating. It should be dimensionally stable under the mechanical, chemical, and thermal stresses that the mask will see during fabrication and use. The multilayer stack 214 is a Bragg mirror having a layer compositions and number of periods designed to reflect EUV radiation. The target EUV radiation for reflectance is defined as 65%. The multilayer stack 214 is composed of alternating layers of silicon (Si) and molybdenum (Mo), however other material pairs could be deployed such as beryllium (Be) and molybdenum (Mo). The Si and Mo combination provides a high peak EUV reflectivity at a wavelength of 13.4-13.6 nm. The mask substrate 212 and the multilayer 214 are the same materials as listed in FIG. 1A for the substrate 112 and multilayer 114, respectively. The fabrications steps involved in producing this mask are shown in FIGS. 2B and 2C.

FIG. 2B shows the EUVL mask structure which is composed of the multilayer stack 214 on the substrate 212 with a hard mask layer 216 on the multilayer and a layer of patterned resist 218 on the hard mask. The pattern 230 is transferred into the resist using a pattern write tool (such as e-beam or laser) and standard mask resist develop procedures.

FIG. 2C shows the EUVL mask after the pattern 230 in the resist has been transferred to the hard mask layer using an etch process such as a plasma etch that selectively removes the hard mask layer 216 in the patterned areas 230. After the pattern transfer into the hard mask the resist layer is removed using a wet or dry resist removal process which removes the resist, but not the hard mask layer.

FIG. 2D shows the EUVL mask similar to FIG. 2C, except shows a situation were defects were inadvertently created in the hardmask layer. FIG. 2D depicts both a clear defect 242 and an opaque defect 240. The clear defect 242 may have been formed by the unintentional removal of some of the hardmask during the hardmask etch process. The opaque defect 240 may have been formed due to an area that was not cleared entirely of resist. Both types of defects must be repaired. Repairing the clear defect requires filling the clear space with a material that is highly selective to the multilayer etch chemistry and also easily removable during the hardmask strip while still maintaining the integrity of the multilayer stack beneath the hard mask. Electron-beam or laser deposition are possible solutions to this type if repair. Repairing the opaque defect requires the removal of the unwanted material of the defect. It is not as critical to maintain the integrity of the multilayers in this instance, as the multilayers in this area will be removed. Hence focused ion beam repair may be a suitable option if any damage induced on the multilayers is contained within the area that will be removed to form a trench.

FIG. 2E shows the final EUVL mask structure after the repair process is completed on a clear defect 254.

FIG. 2F shows an example of an end-pointed etch, which uses an optical endpoint detector with a 648 nm laser. At the beginning of the etch process, it is possible to distinguish between the etching of the Mo layers versus the etching of Si layers by the different laser reflectance of each. In this example, the Mo layer has a higher reflectance than the Si layer. The intensity of the Mo peaks decrease over the duration of the etch process.

FIG. 2G shows an EUVL mask structure 210 after a film 244 has been deposited onto the sidewalls of the etched multilayer to decrease any blur that would occur by partial reflection at the multilayer edges.

It is thus believed that the operation and construction of the present invention will be apparent from the foregoing description. While the method and system shown and described has been characterized as being preferred, it will be readily apparent that various changes and/or modifications could be made wherein without departing from the spirit and scope of the present invention as defined in the following claims.

What is claimed is:

1. A reflective mask used to transform incident radiation into a predetermined pattern which comprises:
a substrate; and
a reflective film stack, the reflective film stack having trenches with sufficient depth and sidewall shape to ensure that the trenches act as absorbers of radiation.

2. The mask of claim 1, also comprising a material deposited over the reflective film stack in those areas not defined by the trenches which is capable of acting as a hard mask while also possessing the desired optical properties at the exposure wavelength.

3. The mask of claim 2, wherein the material deposited over the reflective film stack is transparent to the exposure wavelength.

4. The mask of claim 1, wherein the reflective film stack is a multilayer.

5. The mask of claim 4, wherein the multilayer is composed of Mo and Si.

6. The mask of claim 1, also comprising a liner formed on the sidewalls.

7. The mask of claim 6 wherein the liner material absorbs the incident radiation.

8. The mask of claim 6 wherein the liner material protects the trench sidewalls.

9. A method for forming a reflective mask, comprising the steps of:
selecting a mask blank comprised of a substrate and a reflective film stack;
depositing a hard mask layer on the reflective film stack;
applying a layer of resist to the hard mask layer;
patterning the resist to create regions of resist and regions of exposed hard mask in the desired pattern;
etching the exposed hard mask to create regions of resist and regions of exposed reflective film stack;
stripping the resist to leave patterned hard mask and regions of exposed reflective film stack; and
forming a trench through the open areas of the hard mask by etching the reflective film stack.

10. The method of claim 9 wherein the hard mask is comprised of a material that has selectivity to the underlying film stack.

11. The method of claim 9 wherein the hard mask material is comprised of chromium.

12. The method of claim 9, also comprising the step of patching a clear defect (missing material) in the hard mask by using energy-assisted deposition.

13. The method of claim 9, also comprising the step of removing an opaque defect (extra material) in the hard mask by using energy-assisted film removal.

14. The method of claim 11 wherein the reflective film stack is a multilayer.

15. The method of claim 14 wherein the multilayer is composed of Si and Mo.

16. The method of claim 15 wherein a fluorine reactive ion etch chemistry is used to etch the multilayer film.

17. The method of claim 16, also comprising the step of detecting the endpoint of the etch of the multilayer film.

18. The method of claim 11, also comprising the step of stripping the hard mask once the trench pattern in the multilayer has been created.

19. The method of claim 11, also comprising the step of depositing a sidewall liner on the walls of the trench.

20. The method of claim 19 wherein the sidewall liner is formed by electroplating.

21. The method of claim 19 wherein the sidewall liner is formed by a deposition process.

22. The method of claim 19 wherein the sidewall liner is grown in the presence of a reactive medium.

23. A method for forming a reflective mask, comprising the steps of:
selecting a mask blank comprised of a substrate and a reflective film stack;
depositing a hard mask layer on the reflective film stack;
applying a layer of resist on the hard mask layer;
patterning the resist to create regions of resist and regions of exposed hard mask in the desired pattern;
etching the exposed hard mask to create regions of resist and regions of exposed reflective film stack;
stripping the resist to leave patterned hard mask and regions of exposed reflective film stack;
inspecting and repairing any defects; and
forming a trench though the open areas of the repaired hard mask by etching the reflective film stack;

24. The method of claim 23 wherein the hard mask is comprised of a material that has etch selectivity to the underlying film stack.
